(19) United States
(12) Patent Application Publication
(10) Pub. No.: US 2023/0212065 A1
(43) Pub. Date: Jul. 6, 2023

(54) LOW-E MATERIAL COMPRISING A THICK LAYER BASED ON SILICON OXIDE

(71) Applicant: SAINT-GOBAIN GLASS FRANCE, COURBEVOIE (FR)

(72) Inventors: Yann COHIN, PARIS (FR); Maëlis BANCI, BOURG-LA-REINE (FR); Corinne VICTOR, SAINT-LEU-LA-FORET (FR)

(21) Appl. No.: 17/924,837

(22) PCT Filed: May 7, 2021
(86) PCT No.: PCT/FR2021/050786

§ 371 Date: Nov. 11, 2022

(30) Foreign Application Priority Data
May 12, 2020 (FR) FR2004679

(51) Int. Cl. C03C 17/36; C23C 14/10; C23C 14/08; C23C 14/18; C23C 14/35; F25D 23/06

(52) U.S. Cl. CPC C03C 17/366; C03C 17/3618; C03C 17/3644; C03C 17/3681; C23C 14/10; C23C 14/086; C23C 14/185; C23C 14/352; F25D 23/065; C03C 2218/156; C03C 2217/944

(57) ABSTRACT

A material includes a transparent substrate coated with a stack including at least one functional metal layer based on silver and at least two dielectric coatings, each dielectric coating including at least one dielectric layer, in such a way that each functional metal layer is positioned between two dielectric coatings, wherein the stack includes a layer based on silicon oxide having a thickness of greater than or equal to 12 nm located directly in contact with the substrate.

The invention relates to a material comprising a transparent substrate coated with a stack comprising a silver-based functional metal layer. The invention also relates to the glazed units comprising these materials and also to the use of such materials for manufacturing glazed units.

Silver-based functional metal layers (or silver layers) have advantageous properties of electrical conduction and of reflection of infrared radiation (IR), hence their use in “solar control” glazed units targeted at reducing the amount of solar energy entering and/or in “low-e” glazed units targeted at reducing the amount of energy dissipated towards the outside of a building, vehicle, or device.

These silver layers are deposited between coatings based on dielectric materials, which generally comprise several dielectric layers (hereafter “dielectric coatings”), making it possible to adjust the optical properties of the stack. In addition, these dielectric layers make it possible to protect the silver layer from chemical or mechanical attacks.

The invention relates in particular to a material used to manufacture a glazed unit used as a constituent element of a heating or cooling device.

A heating device comprises an enclosure delimited by one or more walls and heating means so as to enable the enclosure to be heated to an elevated temperature. The heating devices can be chosen among ovens, fireplaces, furnaces . . . . According to the invention, the heating means are separate from the stack of thin layers. Heated automotive glazed units whose stack serves as a heating element do not correspond to a heating device according to the invention.

A cooling device comprises an enclosure delimited by one or more walls and means for cooling the enclosure to a temperature below the normal temperature (20° C.). The cooling devices can be selected from among others:
refrigerators for which the required temperatures vary between 0 and 20° C. (positive cold),
freezers for which the required temperatures are lower than 0° C. (negative cold).

The glazed units used as part of a freezer-type cooling device (negative cold) generally are monolithic glasses.

The glazed units used as constituent elements of a heating or refrigerator-type cooling device (positive cold) generally are multiple glazed units.

According to the invention, a multiple glazed unit comprises at least two substrates held at a distance so as to delimit a space. The faces of the glazed unit are designated from the inside of the heating or cooling device and by numbering the substrate faces from the inside (internal face) to the outside (external face) of the heating or cooling device.

In the case of a multiple glazed unit for a heating device, the different substrates are usually arranged side by side in an open space.

In the case of a multiple glazed unit for a refrigerator-type cooling device, the different substrates are generally connected to each other so as to form a hermetic cavity between two substrates.

These glazed units help to maintain the temperature inside the device at a set temperature while keeping the outer surface of the glazed unit normally cool to the touch for the protection and comfort of users.

The use of a substrate coated with infrared (IR) radiation reflecting functional coating in glazed units used as constituent elements of a heating or cooling device makes it possible:
to decrease the amount of energy dissipated to the outside in the case of a heating device by reflecting the heat into the enclosure,
to decrease the amount of energy entering the enclosure in the case of a cooling device by reflecting the heat to the outside.

The use of these coatings helps to reduce the consumption of the heating or cooling device and the heating or cooling of the glazed unit.

Coatings comprising functional silver-based metallic layers (or silver layers) are the most effective in reducing the emissivity of glazed units while preserving their optical and aesthetic qualities. These coatings ensure better user protection, lower energy consumption, and greater comfort of use.

However, the chemical and thermal resistance and mechanical strength of the coatings comprising these silver-based functional metal layers are often insufficient. This low resistance results in the short-term appearance of defects such as corrosion spots, scratches, or even total or partial tearing of the stack under normal conditions, and even more so under more extreme conditions.

This phenomenon is accentuated when these glazed units are used in heating devices, especially when they are subjected to long and repeated heat treatment cycles at high temperatures in a humid environment.

This phenomenon is also accentuated when these glazed units are used in cooling devices, especially when they are permanently subjected to a humid environment.

These extreme conditions further accelerate the degradation of the silver layers, particularly through dewetting or corrosion of the silver. All defects or scratches, whether due to corrosion or mechanical stresses, are liable to affect not only the optical and energy performance but also the attractiveness of the coated substrate.

The applicant has developed a functional coating that is particularly suitable for these applications. This coating consists of a single silver-based functional layer protected by an underlayer and a blocking overlayer. The dielectric coatings surrounding the functional layer are essentially oxide-based layers.

This coating is particularly suitable for cooling and heating device applications as it has both:
a high chemical durability with a resistance longer than 56 days in the High Humidity test), and
a low emissivity (about 3%).

The excellent chemical durability can be attributed to the nature of its dielectrics which are essentially oxides.

However, in order to be able to be used in heating or cooling devices, the materials must undergo a heat treatment at high temperature such as tempering. However, the functional coating developed by the applicant remains sensitive to overheating, both during its tempering and during its potential use in a heating device. This sensitivity to heat treatment could be due to the nature of its dielectrics, composed exclusively of oxides.

The silver-based functional layer is unstable and dewets during heat treatment at high temperatures. This de-wetting is characterized by the appearance of holes in the silver layer. These holes are called dendritic because of their often branched shape. These holes in the silver layer have two very damaging consequences for the product.

The product becomes blurred (after tempering, since the edge of the holes in the silver layer scatters the light). Visually, this blur corresponds to the appearance of a more or less milky veil. This haze can be inhomogeneous as it can reveal defects on the surface of the glass (drying marks, glass-handling suction cup marks, etc.).

The emissivity of the product, its key performance, is greatly degraded by these holes. Indeed, it can be shown that in each hole, it is no longer the emissivity of the silver layer (3%, for example) that is to be taken into account, but that of the glass (close to 89%). Thus, if the holes represent only 1% of the surface, the emissivity is already degraded by about 1.8 points, going from 3% to almost 5%.

There are a number of patent applications disclosing silver-based functional coatings comprising a thin low index layer which may be silicon oxide-based in contact with the substrate. Among these applications, EP1480920 may be mentioned. The objective of these low index layers is to reduce the blurring following a heat treatment of stacks comprising a silver-based functional layer. These layers would allow reducing the negative impact of glass substrate aging by “regenerating” the surface of a potentially degraded glass substrate following, for example, long storage.

These applications or patents do not address the issue of heating or cooling devices. The maximum thickness of these intermediate layers of silicon oxide is 10 nm. Finally, these applications do not disclose stacks consisting essentially of oxide layers with advantageous chemical durability.

The applicant has surprisingly discovered that this dual optical/emissivity degradation can be largely abolished while maintaining the very good chemical durability of the product. Indeed, some technical solutions allow a strong improvement in the haze when tempering, but without keeping the necessary chemical durability of the material, which is then largely weakened.

The solution of the invention consists of placing an intermediate layer based on silicon oxide with a thickness greater than 12 nm between the glass substrate and the first dielectric layer of the stack.

The solution of the invention has the significant advantage that it does not require any further modification of the stack already developed by the applicant. Indeed, the use of this layer of optical index close to the glass does not require any modification of the stack already developed, because these layers are optically neutral. Light interferences at the glass/SiO2 interface are negligible.

The superior heating resistance in the presence of such an intermediate layer is not only true during tempering, but also when used in a heating device.

For example, the use of a 14 nm layer of silicon oxide in a functional coating has 8 times the resistance to heating at a temperature of 450° C. than the same functional coating without a silicon oxide layer. By 8 times the resistance means that the material with a stack comprising a 14 nm layer of silicon oxide can be heated at the same temperature for eight times as long as the same stack without the silicon oxide layer, before showing the same degree of degradation.

The applicant has found that there is a range of thickness for this silicon oxide layer that must be met in order to have an anti-haze effect and very good chemical durability. The advantageous effects of the invention are not obtained for thicknesses below 12 nm.

In particular, the applicant has found that the use of a silicon oxide layer delays the degradation of the functional coating. However, in order for this delay in degradation to be sufficient to not lead to degradation:
during a heat treatment at high temperature, that is at a temperature of more than 550° C. for several minutes, or
during long and repeated heating cycles (duration of more than 15 minutes) at a temperature of between 100° and 250° C.,
   a minimum thickness of silicon oxide is required, in particular a thickness of at least 12 nm.

Indeed, thanks to the use of a silicon oxide layer of at least 12 nm, the time/temperature couple during heating becomes compatible with a transformation of the glass, such as tempering or bending, without haze or degrading emissivity. On the hardening and bending tools used, the glazed unit comprising a functional coating without a thick silicon oxide layer in contact with the substrate shows haze at time and temperature parameters very close to those needed to achieve flatness, fragmentation, and acceptable shape. The industrial tools used to bend and/or temper substrates comprising functional coatings may furthermore have variabilities. A material must therefore be robust enough to accept these process variabilities. The materials of the invention have this additional strength. The observed delay in degradation (several tens of seconds at 705° C.) is sufficient to ensure that the materials will not be degraded, regardless of the variability of the tempering process.

The invention thus relates to a material comprising a transparent substrate coated with a stack of comprising at least one functional metal layer based on silver and at least two dielectric coatings, each dielectric coating comprising at least one dielectric layer, characterized in that the stack comprises a layer based on silicon oxide having a thickness of greater than or equal to 12 nm located directly in contact with the substrate.

The invention also relates to:
a glazed unit comprising a material according to the invention,
a glazed unit comprising a material according to the invention mounted on a device, on a vehicle, in particular a motor vehicle, or on a building, and
the method of preparing a material or a glazed unit according to the invention,
the use of a glazed unit according to the invention as a solar control and/or low-emissivity glazed unit for the building or vehicles,
a building, vehicle, or device comprising a glazed unit according to the invention.

The invention also relates to a heating or cooling device comprising heating or cooling means and an enclosure delimited by one or more walls, at least one wall of which comprises at least one glazed unit comprising a material according to the invention.

The invention is particularly suitable as a freezer-type cooling device. In this case, the glazed unit can be made of the material (monolithic glazed unit) with preferably the stack located on the face of the substrate in contact with the enclosure.

The glazed unit of the invention is also suitable for all applications requiring the use of a stack comprising silver layers for which resistance to repeated heat treatments and to corrosion in hot and cold humid environments are key parameters. Mention may particularly be made of:
glazed units for oven doors, pyrolytic or not,
glazed units for fireplace insert doors,
glazed units for fireproof doors,
glazed units for heating elements such as radiators and towel dryers.

The invention also relates to the use of a glazed unit as a constituent element of a cooling device, a heating device or a fireproof door, the glazed unit comprising a material according to the invention.

The glazed unit can be selected from multiple glazed units comprising at least two transparent substrates.

The glazed unit can also be made solely of the material according to the invention. In this case, it has only one substrate. It is then a simple glazed unit or monolithic glazed unit.

Throughout the description, the substrate according to the invention is regarded as laid horizontally. The stack of thin layers is deposited above the substrate. The meaning of the expressions “above” and “below” and “lower” and “upper” is to be considered with respect to this orientation. Unless specifically stipulated, the expressions “above” and “below” do not necessarily mean that two layers and/or coatings are positioned in contact with one another. When it is specified that a layer is deposited “in contact” with another layer or with a coating, this means that there cannot be one (or more) layer(s) inserted between these two layers (or layer and coating).

All the light characteristics presented in the description are obtained according to the principles and methods described in the European standard EN 410 relating to the determination of the light and solar characteristics of the glazed units used in the glass for the construction industry. It is considered that the sunlight entering a building goes from the outside to the inside.

The preferred characteristics which appear in the remainder of the description are applicable both to the material according to the invention and, where appropriate, to the glazed units, devices, or method according to the invention.

The material, that is the transparent substrate coated with the stack, is intended to be subjected to a heat treatment at high temperature. Therefore, the stack and the substrate have preferably been subjected to a heat treatment at a high temperature such as tempering, annealing, or bending.

The stack is deposited by magnetic-field-assisted cathode sputtering (magnetron method). According to this advantageous embodiment, all the layers of the stack are deposited by magnetic-field-assisted cathode sputtering.

The material and the glazed unit of the invention are transparent, that is not opaque. According to an advantageous embodiment, the material or the glazed unit according to the invention has a light transmission greater than 35%, greater than 40%, greater than 45% or greater than 50%.

Unless otherwise mentioned, the thicknesses alluded to in the present document are physical thicknesses and the layers are thin layers. Thin layer is understood to mean a layer having a thickness of between 0.1 nm and 100 micrometers.

The stack comprises a silicon oxide-based layer with a thickness greater than 12 nm located directly in contact with the substrate.

The silicon oxide-based layer has a thickness:
greater than or equal to 12 nm, greater than or equal to 13 nm or greater than or equal to 14 nm,
less than or equal to 60 nm, less than or equal to 40 nm, less than or equal to 30 nm, less than or equal to 25 nm, less than or equal to 20 nm or less than or equal to 18 nm.

The silicon oxide-based layer may comprise other elements. These elements can be selected from aluminum, boron, titanium, and zirconium. Preferably, the elements are selected from amongst aluminum, boron, and titanium.

The silicon oxide-based layer may comprise at least 60%, at least 65%, at least 70%, at least 75.0%, at least 80%, or at least 90% by mass of silicon compared to the mass of all elements forming the silicon oxide-based layer other than oxygen.

Preferably, the silicon oxide-based layer comprises not more than 35%, not more than 30%, not more than 20%, or not more than 10% by mass of elements other than silicon compared to the mass of all elements forming the silicon oxide-based layer other than oxygen.

The silicon oxide-based layer may comprise at least 2%, at least 5.0%, at least 8% by mass of aluminum relative to the mass of all the elements forming the silicon oxide-based layer other than oxygen.

The quantities of oxygen and nitrogen in a layer are determined in atomic percentages with respect to the total quantities of oxygen and nitrogen in the layer considered.

According to the invention, the silicon oxide-based layers comprise essentially oxygen and very little nitrogen. The silicon oxide-based layers comprise more than 90%, more than 95%, or 100% in atomic percent of oxygen relative to the oxygen and nitrogen in the silicon oxide-based layer.

The silicon oxide-based layer can be obtained:
by sputtering,
from a silicon metal target or a silicon oxide-based ceramic target.

The silver-based functional metal layer, before or after thermal treatment, comprises at least 95.0%, preferably at least 96.5% and better still at least 98.0% by mass of silver relative to the mass of the functional layer.

Preferably, the silver-based functional metal layer, before thermal treatment, comprises less than 5% or less than 1.0% by mass of metals other than silver, relative to the mass of the silver-based functional metal layer.

The silver-based functional layers have a thickness from 5 to 30 nm, 5 to 25 nm or 7 to 16 nm.

Preferably, the stack comprises just one functional layer. The stack in this case comprises just one functional layer and two dielectric coatings having at least one dielectric layer, so that the functional layer is arranged between two dielectric coatings.

The stack may comprise at least two silver-based functional metal layers and at least three dielectric coatings each having at least one dielectric layer, so that each functional layer is positioned between two dielectric coatings.

The stack is located on at least one of the faces of the transparent substrate.

The stack may comprise blocking layers located below and/or above the silver-based functional metal layer.

The stack can comprise at least one blocking layer, the function of which is to protect the silver layers by preventing possible damage related to the deposition of a dielectric coating or related to a heat treatment. These blocking layers are preferably located in contact with the silver-based functional metal layers.

According to advantageous embodiments, the stack may comprise at least one blocking layer located below and (directly) in contact with a silver-based functional metal layer (under blocking layer) and/or at least one blocking layer located above and (directly) in contact with a silver-based functional metal layer (over blocking layer).

A blocking layer located above a silver-based functional metal layer is referred to as blocking overlayer. A blocking layer located below a silver-based functional metal layer is referred to as blocking underlayer.

The blocking layers are selected from metal layers based on a metal or on a metal alloy, the metal nitride layers, the metal oxide layers and the metal oxynitride layers of one or more elements selected from titanium, nickel, chromium, tantalum and niobium, such as Ti, TiN, TiOx, Nb, NbN, NbOx, Ni, NiN, NiOx, Cr, CrN, CrOx, NiCr, NiCrN, or NiCrOx.

When these blocking layers are deposited in the metal, nitride or oxynitride form, these layers can undergo a partial or complete oxidation according to their thickness and the nature of the layers which surround them, for example, during the deposition of the following layer or by oxidation in contact with the underlying layer.

The blocking layers may be selected from metal layers, in particular an alloy of nickel and chromium (NiCr) or titanium.

Advantageously, the blocking layers are nickel-based metallic layers. Nickel-based metal blocking layers may comprise, (before heat treatment), at least 20%, at least 30%, at least 40%, at least 50%, at least 60%, at least 70%, at least 80%, at least 90%, at least 95%, at least 96%, at least 97%, at least 98%, at least 99%, or 100% by mass of nickel relative to the mass of the nickel-based metal layer.

Nickel-based metal layers can be selected from:
nickel metal layers,
doped nickel metal layers,
nickel alloy-based metal layers.

Nickel alloy-based metal layers can be based on nickel-chromium alloy.

Each blocking layer has a thickness of between 0.1 and 5.0 nm. The thickness of these blocking layers can be:
at least 0.1 nm, at least 0.2 nm or at least 0.4 nm and/or
at most 5.0 nm, at most 2.0 nm, at most 1.0 nm or at most 0.5 nm.

“Dielectric coating” within the meaning of the present invention should be understood as meaning that there may be just one layer or several layers of different materials inside the coating. A “dielectric coating” according to the invention comprises mostly dielectric layers. However, according to the invention, these coatings can also comprise layers of another nature, in particular absorbent layers, for example metallic ones.

A “same” dielectric coating is considered to be:
between the substrate and the first functional layer,
between each silver-based functional metal layer,
above the last functional layer (furthest from the substrate).

“Dielectric layer” within the meaning of the present invention should be understood as meaning that, from the perspective of its nature, the material is “nonmetallic”, that is, is not a metal. In the context of the invention, this term refers to a material with an n/k ratio across the visible spectrum (from 380 nm to 780 nm) equal to or greater than 5. n denotes the real refractive index of the material at a given wavelength and k represents the imaginary part of the refractive index at a given wavelength; the ratio n/k being calculated at a given wavelength being identical for n and for k.

The thickness of a dielectric coating corresponds to the sum of the optical thicknesses of the layers which form it.

The dielectric coatings exhibit a thickness of greater than 15 nm, preferably of between 15 and 200 nm.

The dielectric layers of the dielectric coatings exhibit the following characteristics, alone or in combination:
they are deposited by sputtering assisted by a magnetic field,
they are selected from the oxides or nitrides of one or more elements chosen from titanium, silicon, aluminum, zirconium, tin and zinc,
they have a thickness greater than 2 nm, preferably between 2 and 100 nm

Preferably, the silver-based functional layer is located above a dielectric layer so-called stabilizing or wetting layer made of a material capable of stabilizing the interface with the functional layer. These coatings are usually based on zinc oxide.

Preferably, the silver-based functional layer is located below a dielectric layer so-called stabilizing or wetting layer made of a material capable of stabilizing the interface with the functional layer. These layers are usually based on zinc oxide.

Zinc oxide-based layers may comprise at least 80% or 90% by mass of zinc, relative to the total mass of all the elements constituting the zinc oxide layer, excluding oxygen and nitrogen.

The zinc oxide-based layers may comprise one or more elements selected from aluminum, titanium, niobium, zirconium, magnesium, copper, silver, gold, silicon, molybdenum, nickel, chromium, platinum, indium, tin and hafnium, preferably aluminum.

The zinc oxide-based layers may optionally be doped by means of at least one other element, such as aluminum.

At first glance, the zinc oxide-based layer is not nitrided, however traces may exist.

The layer based on zinc oxide comprises, in increasing order of preference, at least 80%, at least 90%, at least 95%, at least 98%, at least 100% by mass of oxygen relative to the total mass of oxygen.

The dielectric coating located between the substrate and the first functional metal layer and/or a or each dielectric coating located above the first functional silver-based layer has a zinc oxide-based layer comprising at least 80% by mass of zinc relative to the mass of all elements other than oxygen.

Preferably, each dielectric coating has a zinc oxide-based layer comprising at least 80% by mass of zinc relative to the mass of all elements other than oxygen.

Preferably, the dielectric coating located directly below the silver-based functional metal layer has at least one dielectric layer based on zinc oxide, potentially doped with at least one other element, like aluminum. The metal functional layer deposited above a zinc oxide-based layer is either in direct contact or separated by a blocking layer.

In all stacks, the dielectric coating closest to the substrate is called the bottom coating and the dielectric coating farthest from the substrate is called the top coating. Stacks with more than one silver layer also comprise intermediate dielectric coatings located between the bottom and top coatings.

Preferably, the bottom or intermediate coatings comprise a dielectric layer based on zinc oxide located beneath and directly in contact with a silver-based metal layer, or separated from that layer by a blocking underlayer.

Preferably, the dielectric coating located directly above the silver-based functional metal layer comprises at least one dielectric layer based on zinc oxide, potentially doped with at least one other element, like aluminum. The metal functional layer deposited below a zinc oxide-based layer is either in direct contact or separated by a blocking layer.

Preferably, the intermediate or top coatings comprise a dielectric layer based on zinc oxide located above and directly in contact with a silver-based metal layer, or separated from that layer by a blocking overlayer.

The zinc oxide layers have a thickness of:
at least 1.0 nm, at least 2.0 nm, at least 3.0 nm, at least 4.0 nm, or at least 5.0 nm, and/or
at most 25 nm, at most 10 nm or at most 8.0 nm.

The dielectric layers may have a barrier function. Dielectric layers having a barrier function (hereinafter barrier layer) is understood to mean a layer made of a material capable of forming a barrier to the diffusion of oxygen and water at high temperature, originating from the ambient atmosphere or from the transparent substrate, toward the functional layer. Such dielectric layers are chosen among the layers:
based on silicon and/or aluminum and/or zirconium compounds selected from oxides such as SiO2, nitrides such as silicon nitride Si3N4 and aluminum nitrides AlN, and oxynitrides SiOxNy, optionally doped with at least one other element,
based on zinc-tin oxide,
based on titanium oxide.

Preferably, the material comprises one or more layers based on zinc-tin oxide. The zinc-tin oxide-based layers comprise at least 20% by mass of tin relative to the total mass of zinc and tin.

The zinc-tin oxide-based layer comprises at least 20%, at least 30%, at least 40%, at least 50%, at least 60% or at least 80% by mass of tin, relative to the total mass of zinc and tin.

Preferably, the zinc-tin oxide-based layer comprises 40 to 80% by mass of tin relative to the total mass of zinc and tin.

The zinc-tin oxide-based layer has a thickness:
greater than 5 nm, greater than 10 nm, greater than 15 nm, greater than 20 nm or greater than 25 nm,
less than 50 nm, less than 40 nm or less than 35 nm.

The dielectric coating located between the substrate and the first functional metal layer and/or each dielectric coating located above the first functional silver-based layer comprises a zinc-tin oxide-based layer comprising at least 20% by mass of tin relative to the total mass of zinc and tin.

Each dielectric coating may have a zinc-tin oxide-based layer comprising at least 20% by mass of tin relative to the total mass of zinc and tin.

Preferably, the sum of the thicknesses of all the zinc-tin oxide layers in the dielectric coating located between the substrate and the first silver layer is greater than 30%, greater than 40%, greater than 50% or greater than 60% of the total thickness of the dielectric coating.

Preferably, the sum of the thicknesses of all the zinc-tin oxide layers located in the dielectric coating located above a silver functional layer is greater than 50%, greater than 60%, greater than 70% or greater than 75% of the total thickness of the dielectric coating.

Preferably, the sum of the thicknesses of all the oxide-based layers present in the dielectric coating located between the substrate and the first functional metal layer and/or in each dielectric coating located above the first functional silver-based layer is greater than 50%, greater than 60%, greater than 70%, greater than 80% or greater than 90% of the total thickness of the dielectric coating.

The dielectric coating located between the substrate and the first functional metal layer and/or one or each dielectric coating located over the first functional silver layer may consist solely of oxide layer.

Preferably, the stack has at least one zinc oxide dielectric layer and one zinc-tin oxide layer.

Preferably, the dielectric coating located directly below the silver-based functional metal layer has at least one dielectric layer based on zinc oxide and a layer based on zinc-tin oxide.

Preferably, one or each dielectric coating located directly above the silver-based functional metal layer has at least one dielectric layer based on zinc oxide and a layer based on zinc-tin oxide.

Preferably, each dielectric coating has at least one zinc oxide-based dielectric layer and one zinc-tin oxide-based layer.

The stack of thin layers can optionally comprise a protective layer. The protective layer is preferably the final layer of the stack, that is to say the layer the furthest away from the substrate coated with the stack (before heat treatment).

The dielectric coating furthest from the substrate may comprise a protective layer. These layers generally have a thickness comprised between 0.5 and 10 nm, preferably 1 and 5 nm.

This protective layer can be selected from a layer based on titanium, zirconium, hafnium, silicon, zinc and/or tin and a mixture thereof, this or these metals being in metal, oxide or nitride form.

According to one embodiment, the protective layer is based on zirconium oxide and/or titanium oxide, preferably based on zirconium oxide, titanium oxide or titanium-zirconium oxide.

According to one embodiment, the stack comprises:
a dielectric coating below the silver-based functional metal layer,
optionally a blocking layer,
a silver-based functional metal layer,
optionally a blocking layer,
a dielectric coating located above the silver-based functional metal layer optionally comprising a protective layer.

According to one embodiment, the stack comprises:
a dielectric coating located below the silver-based functional metal layer comprising the silicon oxide-based layer, a zinc-tin oxide-based layer, a zinc-oxide-based layer
optionally a blocking layer,
a silver-based functional metal layer,
optionally a blocking layer,
a dielectric coating located above the silver-based functional metal layer comprising a zinc oxide-based layer, a zinc-tin oxide-based layer and optionally a protective layer.

The coated substrate of the stack, or the stack alone, may be intended to undergo heat treatment. The substrate coated with the stack can be bent and/or tempered. However, the present invention also relates to the coated substrate that is not heat-treated.

The stack might not have been heat-treated at a temperature above 500° C., preferably 300° C.

The stack might have been heat-treated at a temperature above 300° C., preferably 500° C.

The heat treatments are chosen from an annealing, for example from a rapid thermal process such as a laser or flash annealing, a tempering and/or a bending. The rapid thermal process is for example described in application WO2008/096089.

The heat treatment temperature (at the stack) is greater than 300° C., preferably greater than 400° C. and better still greater than 500° C.

The coated substrate of the stack is preferably a tempered glass, especially when it is part of a glazed unit used as a constituent element of a cooling device, a heating device or a fireproof door.

The transparent substrates according to the invention are preferably made of a rigid inorganic material, such as made of glass, or are organic, based on polymers (or made of polymer).

The organic transparent substrates according to the invention can also be made of polymer, and are rigid or flexible. Examples of polymers which are suitable according to the invention comprise, in particular:
polyethylene,
polyesters such as polyethylene terephthalate (PET), polybutylene terephthalate (PBT), polyethylene naphthalate (PEN);
polyacrylates such as polymethyl methacrylate (PMMA);
polycarbonates;
polyurethanes;
polyamides;
polyimides;
fluorinated polymers such as fluoroesters like ethylene tetrafluoroethylene (ETFE), polyvinylidene fluoride (PVDF), polychlorotrifluoroethylene (PCTFE), ethylene chlorotrifluoroethylene (ECTFE), fluorinated ethylene-propylene copolymers (FEP),
photocrosslinkable and/or photopolymerizable resins, such as thiolene, polyurethane, urethane-acrylate, polyester-acrylate; and
polythiourethane resins.

The substrate is preferably a sheet of glass or of glass-ceramic.

The substrate is preferably transparent, colorless (it is then a clear or extra-clear glass) or colored, for example blue, gray or bronze. The glass is preferably of soda-lime-silica type but it can also be a glass of borosilicate or alumino-borosilicate type.

According to a preferred embodiment, the substrate is made of glass, particularly soda-lime-silica glass, or of polymer organic material.

The substrate advantageously has at least one dimension greater than or equal to 1 m, indeed even 2 m and even 3 m. The thickness of the substrate generally varies between 0.5 mm and 19 mm, preferably between 0.7 and 9 mm, in particular between 2 and 8 mm, indeed even between 2.8 and 6 mm. The substrate may be flat or curved, indeed even flexible.

The invention also relates to a glazed unit comprising at least a material according to the invention. The invention relates to a glazed unit that can be in the form of a monolithic, laminated or multiple glazed unit, in particular double glazed unit or triple glazed unit.

The glazed unit may be a monolithic glazed unit having 2 faces.

The glazed unit can be a multiple glazed unit comprising two, three or four substrates. In this case, the glazed unit has a material according to the invention, particularly comprising a substrate and one, two, or three additional substrates.

A multiple glazed unit comprises at least one material according to the invention and at least one additional substrate. The material and the additional substrate are either side-by-side or separated by at least one interposed gas gap.

A double glazed unit has two substrates, an outer and an inner substrate, and 4 faces.

A triple glazed unit has three substrates, an outer substrate, a central substrate and an inner substrate, and 6 faces.

In the case of a building, the face 1 is outside the building and is therefore the outer wall of the glazed unit. All other sides are numbered successively. The face inside the building has the highest number.

A laminated glazed unit has at least one structure of first substrate/sheet(s)/second substrate type. The polymer sheet may especially be based on polyvinyl butyral PVB, ethylene vinyl acetate EVA, polyethylene terephthalate PET, polyvinyl chloride PVC. The stack of thin layers is positioned on one at least of the faces of one of the substrates.

These glazed units can be mounted on a building or a vehicle.

This glazed units can be mounted on heating or cooling devices such as oven or refrigerator doors.

The glazed unit may comprise at least one transparent substrate coated with a functional coating other than a stack comprising at least one silver-based functional metal layer such as a coating comprising a transparent conductive oxide (“TCO”). The coating comprising a transparent conductive oxide can be selected from a material based on indium tin oxide (ITO), based on aluminum-doped zinc oxide (ZnO:Al) or boron-doped zinc oxide (ZnO:B), or based on fluorine-doped tin oxide (SnO2:F). These materials are deposited chemically, such as by chemical vapor deposition (“CVD”), possibly plasma enhanced (“PECVD”) or physically, such as by vacuum sputtering, possibly assisted by a magnetic field (“Magnetron”). The presence of this other coating is particularly advantageous in the case of a heating device.

The functional coating other than a stack comprising at least one silver-based functional metal layer may be on the same substrate. The functional coating other than a stack comprising at least one silver-based functional metal layer may be on a different substrate than the one coated with a stack comprising a silver-based functional metal layer. In this case the glazed unit is a multiple glazed unit.

The glazed unit may therefore comprise a functional coating other than a stack comprising a silver-based functional metal layer such as a coating comprising a transparent conductive oxide located:
on the substrate comprising a silver-based functional metal layer, on the face opposite that comprising the silver-based functional metal layer,
on one of the faces of a substrate different from the one comprising a silver-based functional metal layer.

The heating device allows the heating of the enclosure to a high temperature, in particular above 50, 100, 200, 300, 400, 500 or 600° C. The heating device further comprises heating means. These heating means allow the heating of the enclosure to a high temperature, in particular above 50, 100, 200, 300, 400, 500 or 600° C.

The following examples illustrate the invention.

### EXAMPLES

Stacks of thin layers defined below are deposited on substrates made of clear soda-lime glass with a thickness of 4 mm.

For these examples, the conditions of the deposition of the layers deposited by sputtering (“magnetron cathode” sputtering) are summarized in Table 1 below.

TABLE 1

| | | Pressure | |
|---|---|---|---|
| Table | Targets employed | μbar | Gas |
| SiO2 | Si:Al 92/8% by wt | 2-7 | Ar 60% - O₂ 40% |
| SnZnO | Sn:Zn 60/40% by wt | 3-4 | Ar 40-50% - O₂ 50-60% |
| ZnO | Zn:Al 92:8% by wt | 2-4 | Ar 62% - O₂ 38% |
| NiCr | Ni:Cr (80:20% at.) | 2 | Ar at 100% |
| Ag | Ag | 6 | Ar at 100% |
| TiOₓ | TiOx | 2 | Ar 88% - O₂ 12% |

at.: atomic;
wt: weight;
* at 550 nm.

Table 2 below summarizes the deposition conditions of layers based on silicon oxide.

TABLE 2

| | Conditions | Cp-2 | Cp-3 | Cp-4 | Cp-5 | Inv-1 | Inv-2 | Inv-3 | Inv-4 |
|---|---|---|---|---|---|---|---|---|---|
| Cpt 1 | Power (kW) | 25 | 35 | 45 | 60 | 60 | 90 | 60 | 60 |
| | Pressure (μbar) | 5.2 | 5.1 | 5.2 | 5.4 | 4.5 | 6.1 | 4.3 | 2.3 |
| | Ar (sccm) | 1100 | 1100 | 1100 | 1100 | 700 | 1100 | 700 | 700 |
| | O₂ (sccm) | 300 | 350 | 440 | 585 | 540 | 840 | 410 | 480 |
| Cpt 2 | Power (kW) | 0 | 0 | 0 | 0 | 0 | 0 | 60 | 60 |
| | Pressure (μbar) | — | — | — | — | — | — | 2.7 | 4.5 |
| | Ar (sccm) | — | — | — | — | — | — | 700 | 700 |
| | O₂ (sccm) | — | — | — | — | — | — | 300 | 460 |

| | | | | | | | | |
|---|---|---|---|---|---|---|---|---|
| Total power (kW) | 25 | 35 | 45 | 60 | 60 | 90 | 120 | 120 |
| Line speed m/min | 4 | 4 | 4 | 4 | 4 | 4 | 4 | 4 |
| SiO2 thickness (nm) | 5.6 | 8.4 | 11.0 | 11.5 | 12.0 | 14.8 | 14.8 | 14.2 |

Cpt.: Compartment

The materials Cp-1 to Cp-5 and Inv-1 and Inv-2 comprise a layer of SiO2 deposited in a single area. For the materials Inv-3 and Inv-4, the SiO2 layer is deposited in two different areas.

The materials and the physical thicknesses in nanometers (unless otherwise indicated) of each layer or coating of which the stacks are composed are listed in Table 3 below as a function of their positions with regard to the substrate carrying the stack.

TABLE 3

| Glazed unit | | Cp-1 | Cp-2 | Cp-3 | Cp-4 | Cp-5 | Inv-1 | Inv-2 | Inv-3 | Inv-4 |
|---|---|---|---|---|---|---|---|---|---|---|
| DC | TiOx | 2.5 | 2.5 | 2.5 | 2.5 | 2.5 | 2.5 | 2.5 | 2.5 | 2.5 |
| | SnZnO | 30 | 30 | 30 | 30 | 30 | 30 | 30 | 30 | 30 |
| | ZnO | 5 | 5 | 5 | 5 | 5 | 5 | 5 | 5 | 5 |
| BL | NiCr | 0.4 | 0.4 | 0.4 | 0.4 | 0.4 | 0.4 | 0.4 | 0.4 | 0.4 |
| FL | Ag | 13 | 13 | 13 | 13 | 13 | 13 | 13 | 13 | 13 |
| BL | NiCr | 0.1 | 0.1 | 0.1 | 0.1 | 0.1 | 0.1 | 0.1 | 0.1 | 0.1 |
| DC | ZnO | 5 | 5 | 5 | 5 | 5 | 5 | 5 | 5 | 5 |
| | SnZnO | 30 | 30 | 30 | 30 | 30 | 30 | 30 | 30 | 30 |
| | SiO2 | 0 | 5.6 | 8.4 | 11.0 | 11.5 | 12 | 14.8 | 14.8 | 14.2 |
| Sub. | glass | — | — | — | — | — | — | — | — | — |

DC: Dielectric coating;
BL: Blocking layer;
FL: Functional layer

A tempering type heat treatment is performed on the coated substrates at 705° C. for 180 seconds.

### Evaluation of Haze and Chemical Durability

The level of haze was quantified in the following way. The tempered glass is placed on a desk tilted 20 degrees relative to the vertical, in a room with black walls. It is lit by a powerful lamp placed vertically on the desk. The observer stands in front of the desk, 1 m away. In this configuration, a hazy sample shows a marked milky appearance: it scatters the light from the lamp away from its specular reflection area on the glass. On the contrary, a sample without haze does not diffuse any light towards the observer, so it appears dark. The following assessment indicators were used:
“−”: The material is very hazy,
“0”: The material is hazy,
“+”: The material is not hazy.

Chemical durability is evaluated by a high humidity test before (HH) and after heat treatment (TT-HH). The humidity (HH) test consists in storing samples for 56 days at 90% relative humidity and at 60° C. and observing the possible presence of defects, such as corrosion pits. The following assessment indicators were used:
ok: no pitting, the material has no defects after 56 days of testing,
nok: much pitting, the material has defects and therefore does not pass the test.

The results are compiled in Table 4 below:

TABLE 4

| Test | Cp-1 | Cp-2 | Cp-3 | Cp-4 | Cp-5 | Inv-1 | Inv-2 | Inv-3 | Inv-4 |
|---|---|---|---|---|---|---|---|---|---|
| Haze | − | − | 0 | 0 | 0 | + | + | + | + |
| HH | ok | ok | ok | ok | ok | ok | ok | ok | ok |
| TT-HH | ok | ok | ok | ok | ok | ok | ok | ok | ok |

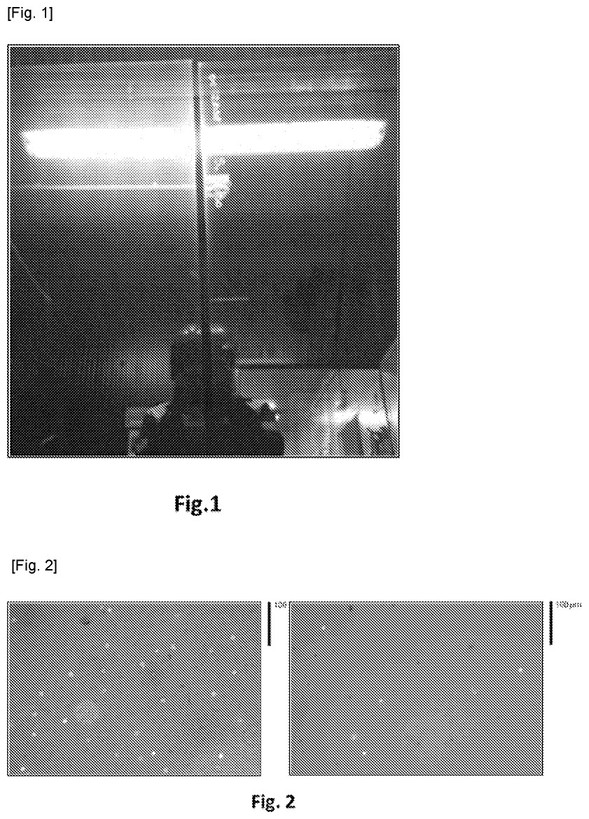

In order to confirm the anti-haze effect, photographs and microscope images were taken. FIG. 1 shows two materials side by side, on the left the material Cp-1 and on the right the material Inv-2. FIG. 2 shows two microscopic images, on the left the material Cp-1 and on the right the material Inv-2. The observations are compiled in Table 5 below.

TABLE 5

| Materials | Photography | Microscope | Observations |
|---|---|---|---|
| Cp-1 | FIG. 1, left | FIG. 2, left | Presence of haze and |
| | | | numerous dendrites |
| Inv-2 | FIG. 1, right, | FIG. 2, right | No haze and few dendrites. |

In the images of the material of the invention, no haze is observed. This is due to the strong decrease in the number of dendrites.

### Study of Emissivity Degradation Based on Heat Treatment Duration

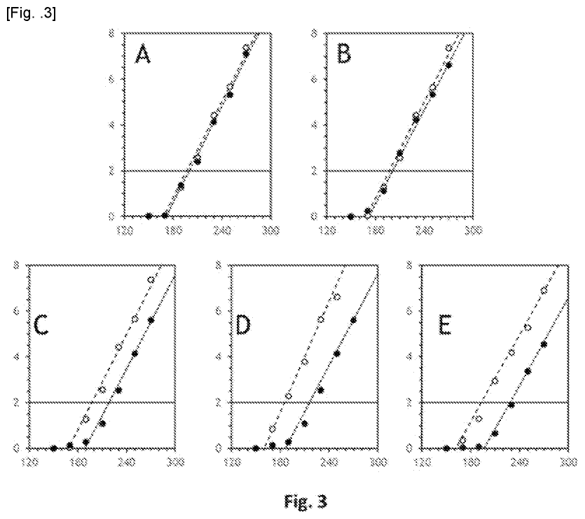

The applicant has found that the advantageous properties of the invention in terms of resistance to heat treatment are attributable to delayed degradation. The delay is illustrated by the curves in FIG. 3. These curves A, B, C, D and E represent the emissivity degradation in percentage points based on heat treatment duration in seconds. The heat treatment is performed at a temperature of 705° C. The material Cp-1 is compared with the materials Cp-3 (Curve A), Cp-4 (Curve B), Inv-2 (Curve C), Inv-3 (Curve D) and Inv-4 (Curve E) respectively. The hollow circles on each curve represent Cp-1, and the solid circles the comparison element. The delay is observed when a layer based on silicon oxide of sufficient thickness is used (curves C, D and E).

Table 6 below highlights the delay in degradation of the solution of the invention. For this purpose, the duration of the heat treatment in seconds is compared, for which 2 points of emissivity degradation are obtained between the material Cp-1 and the materials Cp-3 and Cp-4 respectively, as well as the materials of the invention Inv-2, Inv-3 and Inv-4.

TABLE 6

| | Duration for 2 points | |
|---|---|---|
| Comparative | Emissivity degradation | Delay |
| Cp1/Cp3 | 193 s/Indissociable | <5 s |
| Cp1/Cp4 | 193 s/Indissociable | <5 s |
| Cp1/Inv-2 | 193 s/210 s | 17 s |
| Cp1/Inv-3 | 193 s/219 s | 26 s |
| Cp1/Inv-4 | 193 s/218 s | 25 s |

For thicknesses below 12 nm, the delay is too short to be really useful. With at least 12 nm of SiO2, the time/temperature relationship during heating becomes compatible with a glass transformation, such as tempering or bending without haze, nor degraded emissivity. On the tempering and bending tools used, the glazed unit Cp-1 showed haze at time and temperature parameters very close to those needed to achieve flatness, fragmentation, and acceptable shape. The industrial tools used to bend and/or temper a glazed unit with layer may vary. A glazed unit must therefore be robust enough to accept these method variabilities. Materials Inv-2, Inv-3, and Inv-4 have this additional strength.

1. A material comprising a transparent substrate coated with a stack comprising at least one functional metal layer based on silver and at least two dielectric coatings, each dielectric coating having at least one dielectric layer, so that each functional metal layer is positioned between two dielectric coatings, wherein the stack comprises a layer based on silicon oxide having a thickness of greater than or equal to 12 nm located directly in contact with the substrate.

2. The material according to claim 1, wherein the layer based on silicon oxide has a thickness of greater than or equal to 14 nm.

3. The material according to claim 1, wherein the layer based on silicon oxide has a thickness less than or equal to 60 nm.

4. The material according to claim 1, wherein the dielectric coating located between the substrate and a first functional metal layer of the at least one functional metal layer and/or one or each dielectric coating located above the first functional metal layer has a zinc oxide-based layer comprising at least 80% by mass of zinc relative to the mass of all elements other than oxygen.

5. The material according to claim 1, wherein the dielectric coating located between the substrate and a first functional metal layer of the at least one functional metal layer and/or one or each dielectric coating located above the first functional metal layer has a zinc-tin oxide-based layer comprising at least 20% by mass of tin relative to the total mass of zinc and tin.

6. The material according to claim 1, wherein the stack has at least one zinc oxide-based dielectric layer and a zinc-tin oxide-based layer.

7. The material according to claim 1, wherein each dielectric coating has at least one zinc oxide-based dielectric layer and a zinc-tin oxide-based layer.

8. The material according to claim 1, wherein a sum of the thicknesses of all the oxide-based layers present in the dielectric coating located between the substrate and a first functional metal layer of the at least one functional metal layer and/or in one or each dielectric coating located above the first functional layer is greater than 50% of a total thickness of the dielectric coating.

9. The material according to claim 1, wherein the dielectric coating located between the substrate and a first functional metal layer of the at least one functional metal layer and/or one or each dielectric coating located above the first silver-based functional layer consists solely of oxide layer.

10. The material according to claim 1, wherein all the layers of the stack are deposited by magnetic-field-assisted cathode sputtering.

11. The material according to claim 1, wherein the stack comprises successively:
a dielectric coating located below the functional metal layer and comprising the silicon oxide-based layer, a zinc-tin oxide-based layer, a zinc-oxide-based layer
optionally a blocking layer,
the functional metal layer,
optionally a blocking layer,
a dielectric coating located above the functional metal layer and comprising a zinc oxide-based layer, a zinc-tin oxide-based layer and optionally a protective layer.

12. The material according to claim 1, wherein the stack comprises a single functional layer.

13. The material according to claim 1, wherein the substrate coated with the stack is bent and/or tempered.

14. A glazed unit comprising a material according to claim 1 and one, two, or three additional substrates.

15. The glazed unit according to claim 14, further comprising a functional coating other than the stack comprising a silver the functional metal layer, the functional coating being located:
on the substrate comprising the functional metal layer, and on a face of the substrate opposite a face comprising the functional metal layer, or
on a face of another substrate different from the ene substrate comprising the functional metal layer.

16. A heating or cooling device comprising a heater or cooler and an enclosure delimited by one or more walls, at least one wall of the one or more walls comprises at least one glazed unit comprising a material according to claim 1.

17. A cooling device according to claim 16, wherein the cooling device is a freezer and the at least one glazed unit consists of the material and in that the stack is located on a face of the substrate in contact with the enclosure.

18. A method comprising providing a glazed unit as a constituent element of a cooling device, a heating device or a fireproof door, the glazed unit comprising a material according to claim 1.

19. A method for preparing a material according to claim 1, wherein all the layers of the stack are deposited by magnetic-field-assisted cathode sputtering.

20. The material according to claim 8, wherein the sum of the thicknesses of all the oxide-based layers present in the dielectric coating is greater than 90% the total thickness of the dielectric coating.
